(19) United States
(12) Patent Application Publication
(10) Pub. No.: US 2015/0341032 A1
(43) Pub. Date: Nov. 26, 2015

(54) LOCALLY ASYNCHRONOUS LOGIC CIRCUIT AND METHOD THEREFOR

(71) Applicant: Advanced Micro Devices, Inc., Sunnyvale, CA (US)

(72) Inventor: Greg Sadowski, Cambridge, MA (US)

(73) Assignee: ADVANCED MICRO DEVICES, INC., Sunnyvale, CA (US)

(21) Appl. No.: 14/286,203

(22) Filed: May 23, 2014

(51) Int. Cl. H03K 19/00

(52) U.S. Cl. CPC H03K 19/0016

(57) ABSTRACT

A locally asynchronous logic circuit includes an input latch; a synchronous-to-asynchronous control circuit having an input for receiving a first clock signal, a first output coupled to the latch enable input of the input latch, and a second output for providing a start signal; a predetermined number of stages coupled between the output of the input latch and an output of the locally asynchronous logic circuit, each stage having an asynchronous functional circuit and an associated completion circuit having an input for receiving a corresponding start signal and an output for providing a corresponding done signal; and an asynchronous-to-synchronous control circuit having a first input for receiving a done signal of a preceding stage, and an output for providing a valid signal. The asynchronous-to-synchronous control circuit activates said first valid signal to indicate said output of the locally asynchronous logic circuit is valid.

### FIELD

This disclosure relates generally to digital logic circuits, and more specifically to digital logic circuits suitable for use in clocked systems.

### BACKGROUND

Many different types of digital logic circuits use synchronous clocking. For example, a pipelined microprocessor functional unit may break a processing task into a set of smaller sub-tasks each of which can be performed within a clock period. Each sub-task forms a stage of the pipeline, and the partial results associated with one instruction or operation advance one stage further down the pipeline each clock period. A latch between each pipeline stage captures the results of the previous sub-task synchronously with a clock signal and provides these results to a subsequent pipeline stage. Synchronous pipeline processing is modular, which has led to the popularity of this technique.

However the synchronous pipeline technique also has several drawbacks. First, as the size and complexity of the circuitry grows, the integrated circuit area associated with clock generation and distribution also grows. Second, the increase in the size of the clock tree causes an increase in power consumption. Third, performance is limited by worst case conditions. For example in an array multiplier that uses a carry-save technique that adds partial products in a final carry propagate adder, the clock speed is limited by the time it takes to propagate a carry out of each bit position. This worst-case condition is statistically rare, but the clock speed must be set so that the rare, worst-case condition works properly. The combination of these drawbacks makes this technique less desirable.

### BRIEF DESCRIPTION OF THE DRAWINGS

FIG. 1 illustrates in block diagram form a digital logic system known in the prior art.

FIG. 2 illustrates in block diagram form a digital logic system using a locally asynchronous logic circuit according to some embodiments.

FIG. 3 illustrates in block diagram form another locally asynchronous logic circuit according to some embodiments.

FIG. 4 illustrates in partial block and partial logic diagram form a synchronous-to-asynchronous control circuit that can be used in the locally asynchronous logic circuits of FIGS. 2 and 3 according to some embodiments.

FIG. 5 illustrates a timing diagram showing the operation of the synchronous-to-asynchronous control circuit of FIG. 3.

FIG. 6 illustrates in partial block and partial logic diagram form an intermediate control circuit that can be used in the locally asynchronous logic circuit of FIG. 2 according to some embodiments.

FIG. 7 illustrates a timing diagram showing the operation of the intermediate control circuit of FIG. 6.

FIG. 8 illustrates in partial block and partial logic diagram form an asynchronous-to-synchronous control circuit that can be used in the locally asynchronous logic circuits of FIGS. 2 and 3 according to some embodiments.

FIG. 9 illustrates a timing diagram showing the operation of the asynchronous-to-synchronous control circuit of FIG. 8.

FIG. 10 illustrates in partial block diagram and partial schematic form a completion circuit that can be used in the locally asynchronous logic circuits of FIGS. 2 and 3 according to some embodiments.

FIG. 11 illustrates in partial block diagram and partial schematic form an integrated locally asynchronous stage using another completion circuit that can be used in the locally asynchronous logic circuits of FIGS. 2 and 3 according to some embodiments.

FIG. 12 illustrates in partial block diagram and partial schematic form yet another completion circuit that can be used in the locally asynchronous logic circuits of FIGS. 2 and 3 according to some embodiments.

In the following description, the use of the same reference numerals in different drawings indicates similar or identical items. Unless otherwise noted, the word “coupled” and its associated verb forms include both direct connection and indirect connection by means known in the art, and unless otherwise noted any description of direct connection implies alternate embodiments using suitable forms of indirect connection as well.

### DETAILED DESCRIPTION OF ILLUSTRATIVE EMBODIMENTS

In one form, a locally asynchronous logic circuit includes an input latch, a synchronous-to-asynchronous control circuit, a predetermined number of stages, and an asynchronous-to-synchronous control circuit. The input latch has an input for receiving an input of the locally asynchronous logic circuit, an output, and a latch enable input. The synchronous-to-asynchronous control circuit has an input for receiving a first clock signal, a first output coupled to the latch enable input of the input latch, and a second output for providing a start signal. The predetermined number of stages is coupled between the output of the input latch and an output of the locally asynchronous logic circuit. Each stage has an asynchronous functional circuit and an associated completion circuit having an input for receiving a corresponding start signal and an output for providing a corresponding done signal. The asynchronous-to-synchronous control circuit has a first input for receiving a done signal of a preceding stage, and an output for providing a valid signal. The asynchronous-to-synchronous control circuit activates said first valid signal to indicate said output of the locally asynchronous logic circuit is valid.

In some embodiments, the locally asynchronous logic circuit further comprises a predetermined number of additional stages coupled between the data output of the first stage and the data output of the locally asynchronous logic circuit. Each of these stages may include a latch, an intermediate control circuit, an asynchronous functional circuit, and a completion circuit. The latch has an input coupled to a data output of a preceding stage, a data output, and a latch enable input. The control circuit has an input for receiving the done signal from a preceding stage, a first output coupled to the latch enable input of the latch, and a second output for providing a start signal. The asynchronous functional circuit has an input coupled to the output of the latch, and an output. The completion circuit has an input for receiving the start signal from the preceding stage, and an output for providing the done signal to a subsequent stage.

In another form, a locally asynchronous logic circuit includes a latch, an asynchronous functional circuit, a completion circuit, a synchronous-to-asynchronous control circuit, and an asynchronous-to-synchronous control circuit. The latch has an input for receiving a data input signal, a control input for receiving a latch enable signal, and an output. The asynchronous functional circuit has an input coupled to the latch, and an output and performing a predetermined operation. The completion circuit provides a done signal in response to a start signal based on a characteristic of the asynchronous functional. The synchronous-to-asynchronous control circuit activates the latch enable signal and the start signal after an activation of a first clock signal. The asynchronous-to-synchronous control circuit provides a valid signal in response to the done signal. If the locally asynchronous logic circuit includes only one asynchronous functional circuit, then it can perform adaptation between two different clock domains.

In yet another form, a method for timing an asynchronous logic circuit includes latching first input data and activating a first start signal in response to a first clock signal when a first valid signal is active; performing a first functional operation on the input data so latched and providing first output data in response; determining a first completion time for the first functional operation in response to the first start signal, and providing a first done signal in response to the determining; providing an output of the locally asynchronous logic circuit in response to the first output data and the first done signal; and latching the output of the locally asynchronous logic circuit in response to a second clock signal and the first done signal.

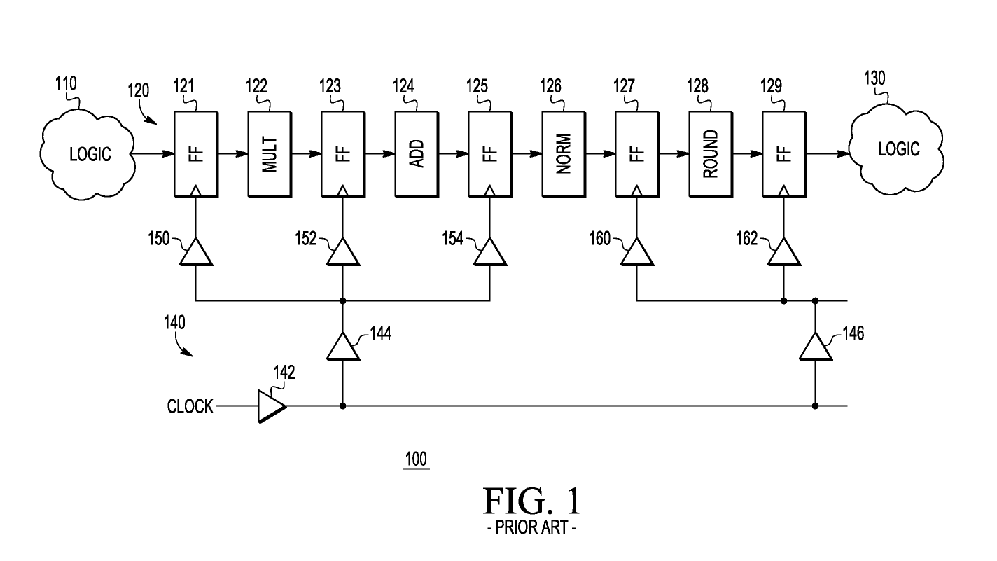

FIG. 1 illustrates in block diagram form a digital logic system 100 known in the prior art. In the example of FIG. 1, digital logic system 100 is part of a pipelined floating-point unit (FPU) typical of FPUs used in modern microprocessors. Digital logic system 100 includes generally a preceding logic block 110, a floating-point pipeline 120, a succeeding logic block 130, and a clock tree 140. Preceding logic block 110 may be, for example, circuitry that collects instructions and operands needed for the instructions before providing them to floating-point pipeline 120. Floating-point pipeline 120 includes several pipeline stages corresponding to sub-steps in floating-point operations, each separated by a clocked flip-flop. In floating-point pipeline 120, these sub-stages include a multiplication stage 122 labeled “MULT”, an addition stage 124 labeled “ADD”, a normalization stage 126 labeled “NORM”, and a rounding stage 128 labeled “ROUND”, separated by clocked flip-flops 121, 123, 125, 127, and 129, such that data is first captured in flip-flop 121 on the rising edge of a clock signal and provided to the input of multiplication stage 122, the output of which is captured in flip-flop 123 on the next rising edge of the clock signal and provided to the input of addition stage 124, and so on until flip-flop 129 captures the output of rounding stage 128 on the rising edge of the clock signal and provides it to the input of succeeding logic block 130.

Clock tree 140 is formed by a set of clock buffers arranged in a hierarchy. At the first level of the hierarchy, a first buffer 142 has an input for receiving a clock signal labeled “CLOCK”, and an output. At a second level of the hierarchy, the output of buffer 142 is distributed in two branches in which a buffer 144 in the first branch has an input for receiving the output of buffer 142, and an output, and a buffer 146 in the second branch has an input for receiving the output of buffer 142, and an output. A third level of the hierarchy includes a first set of buffers 150, 152, and 154 and a second set of buffers 160 and 162. Each of buffers 150, 152, and 154 has an input connected to the output of buffer 144, and an output connected to a clock input of flip-flops 121, 123, and 125, respectively. Each of buffers 160 and 162 has an input connected to the output of buffers 146, and an output connected to a clock input of flip-flops 127 and 129, respectively.

Floating-point pipeline 120 is capable of operating on two double-precision floating point operands having 64 bits each. Each stage also conveys partial results and decoded control signals corresponding to the floating-point instruction being performed. The width of the operands and partial results forces flip-flops 121, 123, 125, 127, and 129 themselves to be wide, and clock tree 140 to supply clock signals with large fan-outs. Thus buffers in clock tree 140 are large and occupy a significant amount of circuit area and consume a significant amount of power when switching.

Moreover floating-point pipeline 120 is divided into stages that can be easily separated and whose corresponding operation can be completed in one (or an integer number of) clock cycles. In the example shown in FIG. 1, floating point pipeline 120 is broken into a multiplication stage, an addition stage, a normalization stage, and a rounding stage, and each instruction requires four clock cycles to complete. These four clock cycles are required to complete one floating point instruction, and the pipeline is broken down into four atomic stages, each of which can complete its corresponding operation in one clock cycle. However a given pipeline stage may not require as much time as allotted, depending on design, transistor characteristics of the manufacturing lot, power supply voltage, temperature, and the operand values themselves. Thus a significant amount of time is wasted on average due to the worst-case design assumptions.

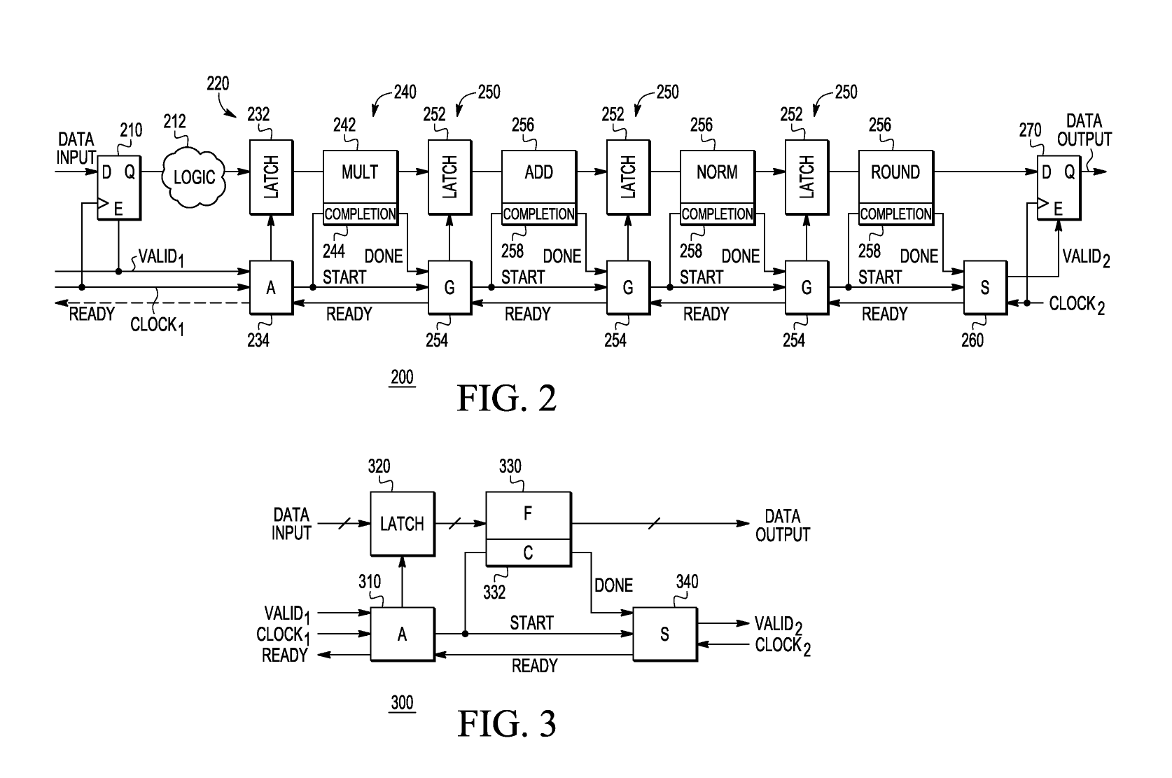

FIG. 2 illustrates in block diagram form a digital logic system 200 using a locally asynchronous logic circuit 220 according to some embodiments. Digital logic system 200 is part of an FPU like digital logic system 100 of FIG. 1, but uses asynchronous techniques to speed processing and eliminate the need for a clock tree to clock pipeline stages. Digital logic system 200 generally includes a latch 210, a combinational logic circuit 212, locally asynchronous logic circuit 220, and an output latch 270.

Latch 210 has a D input for receiving a signal labeled “DATA INPUT”, a Q output, a latch enable input labeled “E” for receiving a control signal labeled “VALID₁”, and a clock input for receiving a clock signal labeled “CLOCK₁”. Combinational logic block 212 has an input connected to the Q output of latch 210, and an output.

Locally asynchronous logic circuit 220 includes an input latch 232, a synchronous-to-asynchronous control circuit 234 labeled “A”, a series of stages associated with a floating point pipeline including a first stage 240 and a set of intermediate stages 250, and an asynchronous-to-synchronous control circuit 260 labeled “S”. Input latch 232 has an input forming the input of locally asynchronous logic circuit 220 and connected to the output of combinational logic circuit 212, a latch enable input, and an output. Synchronous-to-asynchronous control circuit 234 has an input for receiving the VALID₁ signal, an input for receiving the CLOCK₁ signal, an input for receiving a ready signal labeled “READY”, an output connected to the latch enable input of input latch 232, an output for providing a signal labeled “START”, and an output for providing a READY signal. Note that FIG. 2 shows similar signals with the same signal names but they are different signals when conducted between different blocks. First stage 240 includes a multiplication circuit 242 and a completion circuit 244. Multiplication circuit 242 has an input connected to the output of input latch 232, and an output. Completion circuit 244 is associated with multiplication circuit 242 and has an input for receiving the START signal from synchronous-to-asynchronous control circuit 234, and an output for providing a signal labeled “DONE”.

Each intermediate stage 250 includes a latch 252, an intermediate control circuit 254, an asynchronous functional circuit 256, and a completion circuit 258. Latch 252 has an input connected to the output of a preceding asynchronous functional circuit, an enable input, and an output. Intermediate control circuit 254 has inputs for receiving the DONE signal from a completion circuit of a preceding stage, an input for receiving the START signal from a control circuit of the preceding stage, an input for receiving the READY signal from a subsequent stage, an output connected to the enable input of latch 252, an output for providing a START signal to the control circuit of a subsequent stage, and an output for providing the READY signal to the control circuit of a preceding stage. Asynchronous functional circuit 256 has an input connected to the output of latch 252, and an output. Completion circuit 258 is associated with asynchronous functional circuit 256 and has an input for receiving the START signal from the control circuit of a preceding stage, and an output for providing the DONE signal to the control circuit of a succeeding stage. As shown in FIG. 2, the asynchronous functional units in the intermediate stages include an addition stage (ADD), a normalization stage (NORM), and a rounding stage (ROUND).

Asynchronous-to-synchronous control circuit 260 has an input for receiving the DONE signal from the completion circuit of the preceding stage, an input for receiving the START signal from the control circuit of the preceding stage, an input for receiving a second clock signal labeled “CLOCK₂”, and an output for providing a valid signal labeled “VALID₂”. In other embodiments, asynchronous-to-synchronous control circuit 260 also receives a READY signal from a subsequent synchronous circuit. Latch 270 has a D input connected to the output of asynchronous functional circuit 256 of the previous stage, an E input for receiving the VALID₂ signal from asynchronous-to-synchronous control circuit 260, a clock input for receiving the CLOCK₂ signal, and a Q output for providing the DATA OUTPUT signal.

In operation, locally asynchronous logic circuit 220 performs the same floating-point arithmetic operations as the FPU of FIG. 1, but without using pipelined logic and the extensive supporting clock tree. Instead locally asynchronous logic circuit 220 has a front-end interface for receiving the DATA INPUT signal from a clocked logic circuit in a first clock domain and a back-end interface for providing the DATA OUTPUT signal to another clocked logic circuit in a second clock domain, but is asynchronous internally. Thus locally asynchronous logic circuit 220 is able to avoid the need for a clock tree to time its internal operations. In addition to saving circuit area and power, it also completes operations faster by propagating completion results to subsequent stages as soon as they are done, instead of waiting for the next clock edge.

Locally asynchronous logic circuit 220 does so by providing a series of control circuits to control latching of data between adjacent stages implemented by asynchronous functional circuits. It uses three types of control circuits. The first or “A” control circuit 234 is a synchronous-to-asynchronous control circuit. A control circuit 234 controls the transfer of data synchronously with respect to the CLOCK₁ signal once previous circuitry reports that the operand is valid using the VALID₁ signal. In addition, it waits until the activation of the READY signal from the next subsequent stage before providing the DATA INPUT. When both the VALID₁ and READY signals are in their active states, A control circuit 234 activates the latch enable signal to input latch 232 at the next edge (such as the rising edge) of the CLOCK signal, and optionally activates the READY signal to indicate to previous circuitry that it is ready to receive more data to be presented to the asynchronous pipeline at the next edge of the CLOCK₁ signal.

The second or “G” control circuit is an intermediate control circuit that controls the transfer of data from stage to stage down the asynchronous pipeline. G control circuit 254 activates a latch signal to the latch enable input of corresponding latch 252 when the previous stage has completed its assigned operation and the subsequent stage is ready to receive data. Thus, it provides the latch signal when the DONE signal from the previous stage is activated after the previous stage has started and the subsequent stage is ready for new data. G control circuit 254 activates its READY signal after its latch signal to indicate that it is ready to accept more data.

The third or “S” control circuit is an asynchronous-to-synchronous control circuit that controls capturing data at the output of locally asynchronous logic circuit 256 synchronously with the CLOCK₂ signal and validating the data. S control circuit 260 provides the VALID₂ signal to output latch 270 on the activation of the CLOCK₂ signal after it has received the START and DONE signals from the control circuit of previous stage.

FIG. 3 illustrates in block diagram form another locally asynchronous logic circuit 300 according to some embodiments. Locally asynchronous logic circuit 300 includes an “A” control circuit 310, a latch 320, an asynchronous functional circuit labeled “F” 330, an associated completion circuit 332 labeled “C”, and an “S” control circuit 340. Control circuit 310 has input for receiving a VALID₁ signal, an input for receiving a CLOCK₁ signal, an input for receiving a READY input signal, an output for providing a START signal, an output for providing a latch enable signal, and an output for providing a READY output signal to a preceding logic circuit, and. Latch 320 has an input for receiving the DATA INPUT signal, an output, and a latch enable input connected to the latch enable output of control circuit 310. Asynchronous functional circuit 330 has an input connected to the output of latch 320, and an output for providing the DATA OUTPUT signal. Completion circuit 332 has an input from receiving the START signal from A control circuit 310, and an output for providing the DONE signal. S control circuit 340 has inputs for receiving the START and DONE signals, an input for receiving the CLOCK₂ signal, an output for providing the READY signal to control circuit 310, and an output for providing the VALID₂ signal.

In operation, locally asynchronous logic circuit 300 is a special case of locally asynchronous logic circuit 220 of FIG. 2 in which there are no intermediate stages. Thus asynchronous logic circuit 300 has an A control circuit 310 and an S control circuit 340, but no “G” control circuit. Locally asynchronous logic circuit 300 is useful to perform an operation using a single asynchronous functional circuit, especially at the interface between two different clock domains.

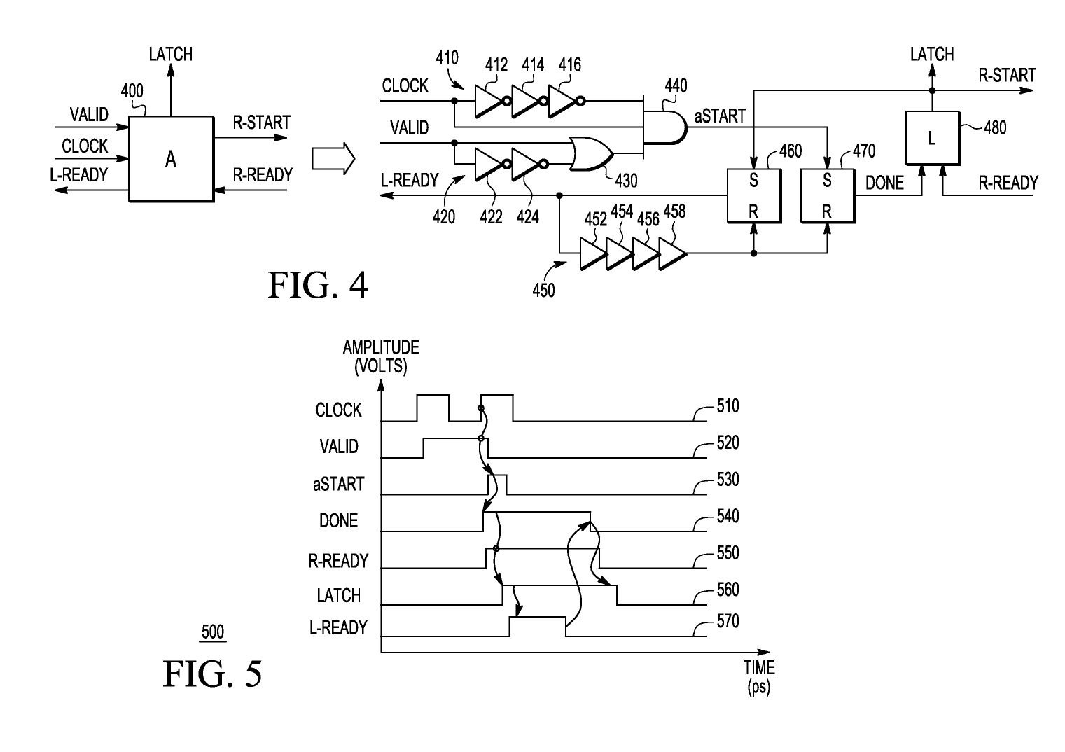

FIG. 4 illustrates in partial block and partial logic diagram form a synchronous-to-asynchronous control circuit 400 that can be used in locally asynchronous logic circuits 220 and 300 of FIGS. 2 and 3, respectively, according to some embodiments. Synchronous-to-asynchronous control circuit 400 is labeled “A” and has input for receiving a VALID input signal from a preceding stage, an input for receiving a CLOCK signal from the preceding stage, an input for receiving a READY signal from a subsequent stage labeled “R-READY”, an output for providing a START signal labeled “R-START” to the subsequent stage, and an output for providing a latch enable signal labeled “LATCH”. As illustrated herein, the operations proceed from left to right; thus signals with an L prefix are associated with leftward (preceding) stages, and signals with an R prefix are associated with rightward (succeeding) stages.

Synchronous-to-asynchronous control circuit 400 includes generally a delay chain 410, a delay chain 420, an OR gate 430, an AND gate 440, a delay chain 450, S-R flip-flops 460 and 470, and a logic circuit 480 labeled “L”. Delay chain 410 includes inverters 412, 414, and 416. Inverter 412 has an input for receiving the CLOCK signal, and an output. Inverter 414 has an input connected to the output of inverter 412, and an output. Inverter 416 has an input connected to the output of inverter 414, and an output. Delay chain 420 includes inverters 422 and 424. Inverter 422 has an input for receiving the VALID signal, and an output. Inverter 424 has an input connected to the output of inverter 422, and an output. OR gate 430 has a first input for receiving the VALID signal, a second input connected to the output of inverter 424, and an output. AND gate 440 has a first input connected to the output of inverter 416, a second input for receiving the CLOCK signal, a third input connected to the output of OR gate 430, and an output for providing a signal labeled “aSTART”. Delay circuit 450 includes buffers 452, 454, 456, and 458. Buffer 452 has an input for receiving the L-READY signal, and an output. Buffer 454 has an input connected to the output of buffer 452, and an output. Buffer 456 has an input connected to the output of buffer 454, and an output. Buffer 458 has an input connected to the output of buffer 456, and an output. SR flip-flop 460 has a set (S) input for receiving the LATCH signal, a reset (R) input connected to the output of buffer 458, and an output for providing the L-READY signal. SR flip-flop 470 as an S input for receiving the aSTART signal, an R input connected to the output of buffer 458, and an output for providing a signal labeled “DONE”. Logic circuit 480 has a first input for receiving the DONE signal, a second input for receiving the R-READY signal, and an output for providing the LATCH signal, which in synchronous-to-asynchronous control circuit 400 is the same as the R-START signal.

FIG. 5 illustrates a timing diagram 500 showing the operation of synchronous-to-asynchronous control circuit 400 of FIG. 4. In FIG. 5, the horizontal axis represents time in picoseconds (ps), and the vertical axis represents the amplitude of several signals in volts. These signals include the CLOCK signal shown by waveform 510, the VALID signal shown by waveform 520, the aSTART signal shown by waveform 530, the DONE signal shown by waveform 540, the R-READY signal shown by waveform 550, the LATCH signal shown by waveform 560, and the L-READY signal shown by waveform 570. Timing diagram 500 shows two cycles of the CLOCK signal relevant to generating the LATCH signal. The CLOCK signal may be a free-running clock signal but may also be a gated clock signal that operates only when the locally asynchronous logic circuit is needed.

Now considering FIGS. 4 and 5 together, synchronous-to-asynchronous control circuit 400 uses delay chain 410 to provide a narrow time in which the CLOCK signal is at a logic high and the delayed, inverted CLOCK signal is also at a logic high. Conversely, OR gate 430 and delay chain 420 lengthen the logic high at the output of OR gate 430 beyond the inactivation of the VALID signal for a time determined by the delay time through inverters 422 and 424. Thus AND gate 440 provides signal aSTART if the VALID signal so modified is active at a logic high during a pulse generated on the low-to-high transition of the CLOCK signal. At a first low-to-high transition of the CLOCK signal, the VALID signal is inactive, so synchronous-to-asynchronous control circuit 400 keeps the aSTART, DONE, LATCH, and L-READY signal inactive. Control circuitry from previous synchronous logic subsequently activates the VALID signal which remains high at the subsequent low-to-high transition of the CLOCK signal, and AND gate 440 pulses the aSTART signal a propagation delay afterward in response. The activation of the aSTART signal sets flip-flop 470 and activates the DONE signal, and when R-READY received from the control circuit (G or S type) of a subsequent stage is also at a logic high, L circuit 480 activates the LATCH/R-START signal to cause input data to be latched into the first stage of the locally asynchronous logic circuit. The activation of the LATCH/R-START signal sets flop-flop 460, causing the activation of the L-READY signal a propagation delay afterward. A delay time after the activation of the L-READY signal determined by delay chain 450, flip-flops 460 and 470 are reset, which causes the de-activation of the DONE signal, but the LATCH/R-START signal remains active while the R-READY signal received from the control circuit (G or S type) of the subsequent stage remains active. In response to the subsequent de-activation of the R-READY signal, logic circuit 480 deactivates the LATCH/R-START signal since both of its inputs are at a logic low. At this time, synchronous-to-asynchronous control circuit 400 is re-armed for the next cycle.

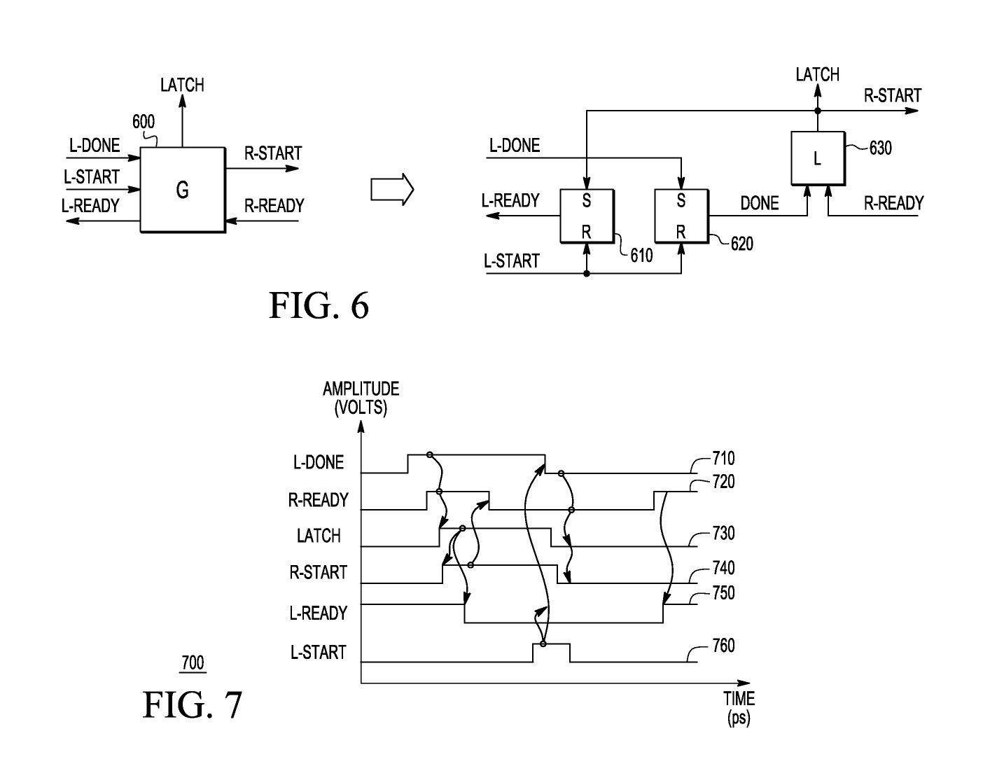

FIG. 6 illustrates in block diagram form an intermediate control circuit 600 that can be used in locally asynchronous logic circuit 220 of FIG. 2 according to some embodiments. Intermediate control circuit 600 is labeled “G” and has input for receiving the L-DONE and L-START signals from the preceding stage, an input for receiving an R-READY signal from a subsequent stage, an output for providing an LATCH signal to the corresponding intermediate stage latch, an output for providing the R-START signal to the subsequent stage, and an output for providing an L-READY signal to a preceding stage.

Intermediate control circuit 600 includes generally SR flip-flops 610 and 620 and a logic circuit 630. Flip-flop 610 has an S input for receiving the R-START signal, an R input for receiving the L-START signal, and an output for providing the L-READY signal. Flip-flop 620 has an S input for receiving the L-DONE signal, an R input for receiving the L-START signal, and an output for providing a DONE signal. Logic circuit 630 has a first input for receiving the DONE signal, a second input for receiving the R-READY signal, and an output for providing the LATCH signal, which in intermediate control circuit 600 is the same as the R-START signal.

FIG. 7 illustrates a timing diagram showing the operation of intermediate control circuit 600 of FIG. 6. In FIG. 7, the horizontal axis represents time in picoseconds (ps), and the vertical axis represents the amplitude of several signals in volts. These signals include the L-DONE signal shown by waveform 710, the R-READY signal shown by waveform 720, the LATCH signal shown by waveform 730, the R-START signal shown by waveform 740, the L-READY signal shown by waveform 750, and the L-START signal shown by waveform 760. The operation of intermediate control circuit 600 starts in response to the activation of the L-DONE signal from the completion circuit of the preceding stage.

Now considering FIGS. 6 and 7 together, the activation of the L-DONE signal sets SR flip-flop 620, which activates the DONE signal (not shown in timing diagram 700) to the first input of logic circuit 630. Upon the activation of the R-READY signal from the control circuit (G or S type) of the subsequent stage, logic circuit 630 activates the LATCH/R-START signal. The activation of the LATCH/R-START signal sets flip-flop 610, which activates the L-READY signal to the control circuit (A or G type) of the preceding stage. When the L-START signal is subsequently activated by the control circuit of the preceding stage, it resets flip-flops 610 and 620, causing the de-activation of the L-READY and DONE signals. When both the DONE and the R-READY signals are inactive, logic circuit 630 deactivates the LATCH/R-START signal, and intermediate control circuit 600 is now re-armed and waiting for the transfer of more data from the preceding stage.

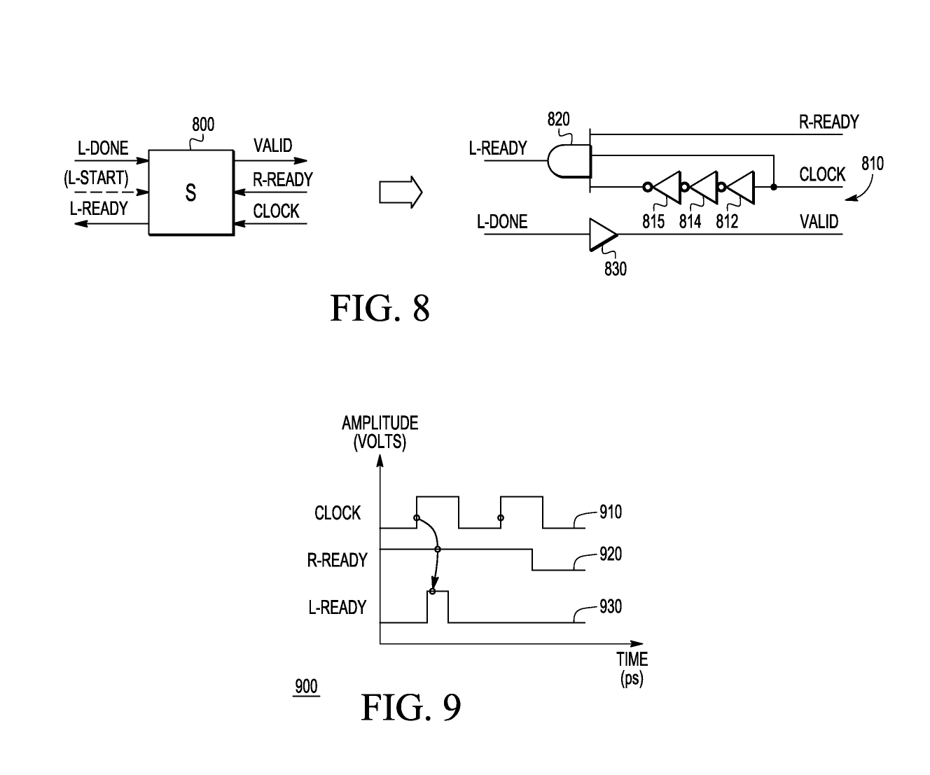

FIG. 8 illustrates in partial block and partial logic diagram form an asynchronous-to-synchronous control circuit 800 that can be used in locally asynchronous logic circuits 220 and 300 of FIGS. 2 and 3 according to some embodiments. Asynchronous-to-synchronous control circuit 800 has an input for receiving the L-DONE signal from the completion circuit of the preceding stage, inputs for receiving the R-READY and CLOCK signals from a subsequent synchronous circuit, and an output for providing the VALID signal to the subsequent synchronous circuit. The L-START signal is shown in phantom as an input but is not used in asynchronous-to-synchronous control circuit 800.

Asynchronous-to-synchronous control circuit 800 includes generally a delay chain 810, an AND gate 820, and a buffer 830. Delay chain 810 includes inverters 812, 814, and 816. Inverter 812 has an input for receiving the CLOCK signal from the subsequent synchronous circuit, and an output. Inverter 814 has an input connected to the output of inverter 812, and an output. Inverter 816 has an input connected to the output of inverter 814, and an output. AND gate 820 has a first input for receiving the R-READY signal from the subsequent synchronous circuit, a second input for receiving the CLOCK signal from the subsequent synchronous circuit, a third input connected the output of inverter 816, and an output for providing the L-READY signal. Buffer 830 has an input for receiving the L-DONE signal from the control circuit of the preceding stage, and an output for providing the VALID signal to the subsequent synchronous circuit.

FIG. 9 illustrates a timing diagram 900 showing the operation of the asynchronous-to-synchronous control circuit of FIG. 8. In FIG. 9, the horizontal axis represents time in picoseconds (ps), and the vertical axis represents the amplitude of three signals in volts. These signals include the CLOCK signal shown by waveform 910, the R-READY signal shown by waveform 920, and the L-READY signal shown by waveform 930.

Now considering FIGS. 8 and 9 together, asynchronous-to-synchronous control circuit 800 activates the VALID signal in response to the activation of the L-DONE signal. It uses inverting delay chain 810 to define a narrow time period in which the CLOCK signal is at a logic high and the delayed, inverted CLOCK signal is also at a logic high. Thus AND gate 820 pulses the L-READY signal for a short period defined by the delay through delay chain 810 if the R-READY signal is active when the CLOCK signal transitions to a logic high.

Various techniques may be used to design the completion detection circuit associated with each an asynchronous functional circuit. A very simple approach would be to use a static delay line that activates the DONE signal a static delay after the activation of the START signal. This delay line would have the same number of logic levels as the corresponding asynchronous functional circuit. Another very simple approach would be a combinational circuit that uses signals already generated by the corresponding asynchronous functional circuit that indicate operation completion. In this case, the completion circuit will be reset in response an activation of the START signal, and it will activate the DONE signal in response to one or more logic signals being in certain corresponding logic states. These circuits will be appropriate for use with some asynchronous functional circuits, but not others, such as those whose completion times depend on dynamically changing values. However other completion detection circuits may be advantageously used when the asynchronous functional circuit does not generate outputs that directly indicate operation completion. Examples of these techniques will now be described.

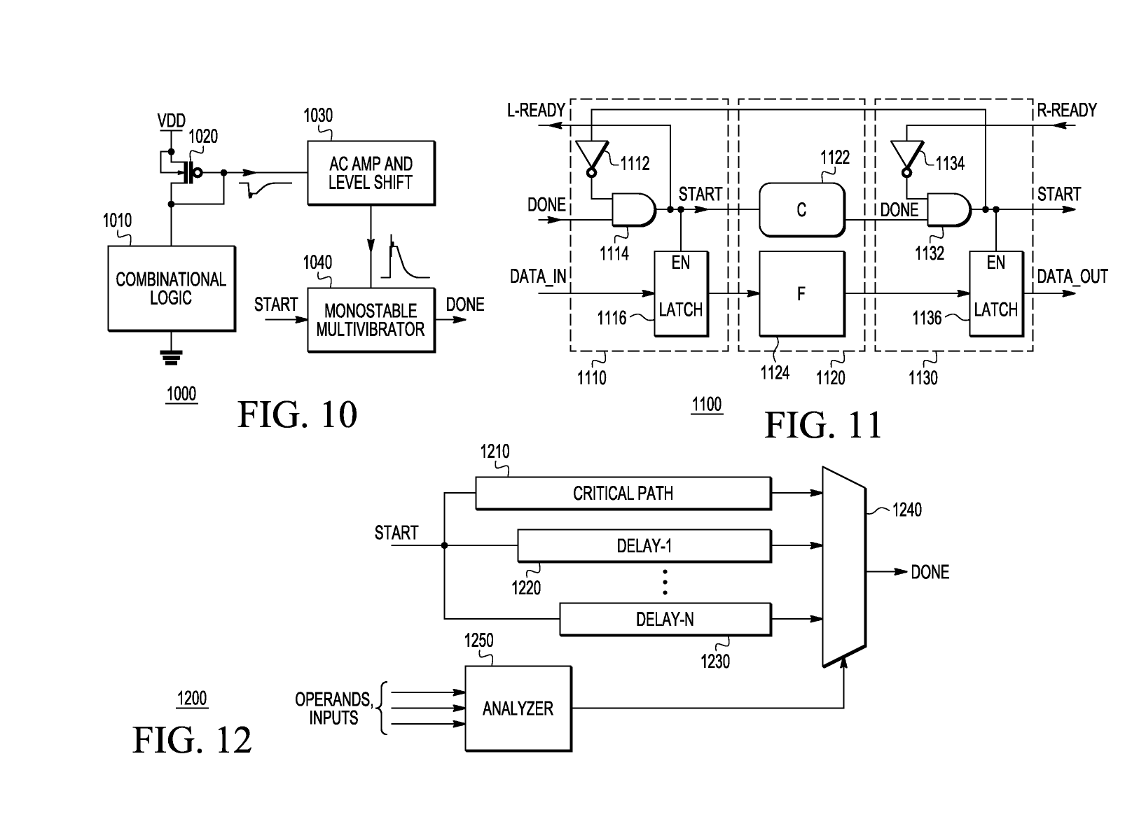

FIG. 10 illustrates in partial block diagram and partial schematic form a completion circuit 1000 that can be used in locally asynchronous logic circuits 220 and 300 of FIGS. 2 and 3 according to some embodiments. Completion circuit 1000 uses current sensing and includes a combinational logic circuit 1010, a P-channel MOS transistor 1020, a dynamic (AC) amplifier and level shifter circuit 1030, and a monostable multivibrator 1040. Combinational logic circuit 1010 is connected between an output terminal and a ground power supply voltage terminal. P-channel transistor 1020 has a source connected to a more-positive power supply voltage terminal, a gate, and a drain connected to the gate thereof and to the output of completion circuit 1000. AC amplifier and level shifter 1030 has an input connected to the drain of transistor 1020, and an output. Monostable multivibrator 1040 has an input connected to the output of AC amplifier and level shifter circuit 1030, a second input for receiving a START signal, and an output for providing the DONE signal.

In operation, completion circuit 1000 uses current sensing to determine when to activate the DONE signal. It uses combinational logic circuit 1010 to approximate the operation of the corresponding asynchronous functional circuit and relies on a correlation between current drawn and time of completion. In this case, combinational logic circuit 1010 sinks a current corresponding to the current drawn in the asynchronous functional circuit. For example, combinational logic circuit 1010 may draw the largest amount of current during computation and this current may settle significantly around the time of completion. Transistor 1020 is a low-threshold, low-resistance transistor that develops a drain voltage corresponding to this current that is compressed logarithmically. Thus a large current draw will correspond to a large negative-going drop in voltage. AC amplifier and level shifter circuit 1030 is an AC-coupled amplifier that inverts and amplifies this waveform, and monostable multivibrator 1040 converts it into a DONE signal whose pulse width corresponds to the propagation time through the asynchronous functional circuit as shown. Completion circuit 1000 is a relatively simple circuit and thus is small in size, and the transistors and other circuit elements in combinational logic circuit 1010 are sized to match corresponding transistors in the asynchronous functional circuit. Thus, the delay through combinational logic circuit 1010 will track the processing delay through the corresponding asynchronous functional circuit over process, voltage, and temperature. Alternatively, combinational logic circuit 1010 may be the asynchronous functional circuit itself. While it is simple and thus appropriate for certain types of asynchronous functional circuits, it is unable to account for variations in delay caused by data operand patterns.

FIG. 11 illustrates in partial block diagram and partial schematic form a portion of a locally asynchronous logic circuit 1100 according to some embodiments. Locally asynchronous logic circuit 1100 generally includes an input portion 1110, an asynchronous functional circuit portion 1120, and an output portion 1130.

Input portion 1110 includes an inverter 1112, an AND gate 1114, and a latch 1116. Inverter 1112 has an input for receiving a START signal, and an output. AND gate 1114 has a first input connected the output of inverter 1112, a second input for receiving a DONE signal from the completion circuit of a preceding stage, and an output for providing a START signal which is also the L-READY signal. Latch 1116 has an input for receiving a data input signal labeled “DATA_IN”, an enable (EN) input connected to the output of AND gate 1114, and an output.

Asynchronous functional circuit portion 1120 includes a completion circuit 1122 labeled “C”, and an asynchronous functional circuit 1124 labeled “F”. Completion circuit 1122 has an input connected to the output of AND gate 1114, and an output. Asynchronous functional circuit 1124 has an input connected to the output of latch 1116, and an output.

Output portion 1130 includes an AND gate 1132, an inverter 1134, and a latch 1136. AND gate 1132 has a first input, a second input connected to the output of completion circuit 1122, and an output for providing the START signal. Inverter 1134 has an input for receiving the R-READY signal, and an output connected to the first input of AND gate 1132. Latch 1136 has a data input, an enable input (EN) connected to the output of AND gate 1132, and an data output for providing a signal labeled “DATA_OUT”. Note that output portion 1130 forms the input portion of a subsequent stage.

Locally asynchronous logic circuit 1100 illustrates how certain functions can be simply and efficiently combined. In response to the activation of signal R-READY, inverter 1134 provides a logic low at the first input of AND gate 1132, which deactivates the START signal and causes inverter 1112 to provide a logic high at the first input of AND gate 1114. When the control circuit of the preceding stage activates the DONE signal, AND gate 1114 activates the START signal, causing latch 1116 to latch the DATA_IN signal and provide it to asynchronous functional circuit 1124. At the same time, completion circuit 1122 determines the delay through asynchronous functional circuit and eventually activates the output thereof. For example, completion circuit 1122 can be a simple delay chain to represent the worst-case delay through asynchronous functional circuit 1124. When the succeeding stage de-activates the R-READY signal, inverter 1134 provides a logic high to the first input of AND gate 1132. When both of its inputs are high, AND gate 1132 activates the START signal, causing latch 1136 to latch the output of asynchronous functional circuit 1124 and provide it as the DATA_OUT signal to the asynchronous functional circuit of the succeeding stage. Thus locally asynchronous logic circuit 1100 combines the control and completion functions of a stage simply and efficiently.

FIG. 12 illustrates in partial block diagram and partial schematic form yet another completion circuit 1200 that can be used in locally asynchronous logic circuits 220 and 300 of FIGS. 2 and 3 according to some embodiments. Completion circuit 1200 includes generally a set of delay circuits including representative delay circuits 1210, 1220, and 1230, a multiplexer 1240, and an analyzer circuit 1250. Delay circuit 1210 corresponds to a critical path delay and has an input for receiving the START signal, and an output. Delay circuit 1220 corresponds to a first representative delay labeled “DELAY-1” and has an input for receiving the START signal, and an output. Delay circuit 1230 corresponds to N^{th} representative delay labeled “DELAY-N” and has an input for receiving the START signal, and an output. Multiplexer 1240 has N+1 inputs corresponding to the outputs of the delay circuits, a control input, and an output for providing the DONE signal. Analyzer circuit 1250 has inputs for receiving various operands labeled “OPERAND INPUTS” and shown in FIG. 12 as a set of three inputs, and an output connected to the control input of multiplexer 1240.

Completion circuit 1200 takes into account the data dependencies inherent in certain types of asynchronous functional circuits, such as multiplication circuit 242 of FIG. 2. Thus for example if analyzer circuit 1250 determines that the input operands will result in a certain minimal number of carries, then it will select the input of multiplexer 1240 corresponding to delay circuit 1230. On the other hand if analyzer circuit 1250 determines that the input operands will result in a certain high number of carries corresponding to the slowest operation, then it will select the input of multiplexer 1240 corresponding to delay circuit 1210. Since the number of possibilities during the multiplication of two double precision floating point numbers is very large, analyzer circuit 1250 can determine which of a representative number of delays to select based on the worst-case delay over ranges of operand values so the completion circuit 1200 can be implemented in a reasonable size.

The circuits of FIGS. 2-6, 8, and 10-12 or portions thereof may be described or represented by a computer accessible data structure in the form of a database or other data structure which can be read by a program and used, directly or indirectly, to fabricate integrated circuits with these circuits. For example, this data structure may be a behavioral-level description or register-transfer level (RTL) description of the hardware functionality in a high level design language (HDL) such as Verilog or VHDL. The description may be read by a synthesis tool which may synthesize the description to produce a netlist comprising a list of gates from a synthesis library. The netlist comprises a set of gates that also represent the functionality of the hardware comprising integrated circuits with the circuits of FIGS. 2-6, 8, and 10-12. The netlist may then be placed and routed to produce a data set describing geometric shapes to be applied to masks. The masks may then be used in various semiconductor fabrication steps to produce integrated circuits of FIGS. 2-6, 8, and 10-12. Alternatively, the database on the computer accessible storage medium may be the netlist (with or without the synthesis library) or the data set, as desired, or Graphic Data System (GDS) II data.

While particular embodiments have been described, various modifications to these embodiments will be apparent to those skilled in the art. For example, a locally asynchronous logic circuit can be formed using the techniques and circuits described above to convert a circuit that was previously pipelined, such a floating point execution unit, or to design a new circuit. Thus the actual functions performed in the stages will vary between embodiments. Moreover the various completion detection circuits may be used in addition to the completion detection circuits described above using critical path analysis, current sensing, or operand analysis.

Accordingly, it is intended by the appended claims to cover all modifications of the disclosed embodiments that fall within the scope of the disclosed embodiments.

What is claimed is:

1. A locally asynchronous logic circuit comprising:
an input latch having an input for receiving an input of the locally asynchronous logic circuit, an output, and a latch enable input;
a synchronous-to-asynchronous control circuit having an input for receiving a first clock signal, a first output coupled to said latch enable input of said input latch, and a second output for providing a start signal;
a predetermined number of stages coupled between said output of said input latch and an output of the locally asynchronous logic circuit, each stage having an asynchronous functional circuit and an associated completion circuit having an input for receiving a corresponding start signal and an output for providing a corresponding done signal; and
an asynchronous-to-synchronous control circuit having a first input for receiving a done signal of a preceding stage, and an output for providing a first valid signal,
wherein said asynchronous-to-synchronous control circuit activates said first valid signal to indicate said output of the locally asynchronous logic circuit is valid.

2. The locally asynchronous logic circuit of claim 1 wherein said synchronous-to-asynchronous control circuit further activates said latch enable signal in response to said first clock signal when a second valid signal is active.

3. The locally asynchronous logic circuit of claim 2 wherein said synchronous-to-asynchronous control circuit activates said start signal further in response to a ready signal being active.

4. The locally asynchronous logic circuit of claim 1 wherein said asynchronous-to-synchronous control circuit activates a second valid signal in response said done signal.

5. The locally asynchronous logic circuit of claim 4 wherein said asynchronous-to-synchronous control circuit further activates said first valid signal in response to a ready received from a subsequent synchronous circuit.

6. The locally asynchronous logic circuit of claim 1 wherein said completion circuit of at least one of said predetermined number of stages provides said done signal based on at least a portion of an input of an associated asynchronous functional circuit.

7. The locally asynchronous logic circuit of claim 6 wherein said completion circuit further comprises:
a plurality of delay paths each having an input for receiving having an input for receiving a start signal from a preceding stage, and an output;
a multiplexer having inputs coupled to outputs of each of said plurality of delay paths and an output for providing said done signal; and
an analyzer circuit responsive to said output of said latch for selecting one of said inputs of said multiplexer.

8. The locally asynchronous logic circuit of claim 1 wherein said completion circuit provides said done signal based on a dynamic characteristic of said asynchronous functional circuit.

9. The locally asynchronous logic circuit of claim 8 wherein said dynamic characteristic comprises a current.

10. The locally asynchronous logic circuit of claim 1 wherein said completion circuit provides said done signal based on a slowest path delay of said asynchronous functional circuit.

11. The locally asynchronous logic circuit of claim 10 wherein said predetermined number is greater than one, and each of said predetermined number of stages besides a first stage comprises:
a latch having an input coupled to a data output of a preceding stage, a data output, and a latch enable input;
a control circuit having an input for receiving said done signal from a preceding stage, a first output coupled to said latch enable input of said latch, and a second output for providing a start signal;
an asynchronous functional circuit having an input coupled to said output of said latch, and an output; and
a completion circuit having an input for receiving said start signal from said preceding stage, and an output for providing said done signal to a subsequent stage.

12. The locally asynchronous logic circuit of claim 11 wherein the locally asynchronous logic circuit is an arithmetic unit, and asynchronous functional circuits of said predetermined number of stages comprise a multiplier, an adder, a normalizer, and a rounder.

13. A locally asynchronous logic circuit comprising:
a latch having an input for receiving a data input signal, a control input for receiving a latch enable signal, and an output;
an asynchronous functional circuit having an input coupled to said latch, and an output and performing a predetermined operation;
a completion circuit for providing a done signal in response to a start signal based on a characteristic of said asynchronous functional circuit;
a synchronous-to-asynchronous control circuit for activating said latch enable signal and said start signal after an activation of a first clock signal; and
an asynchronous-to-synchronous control circuit for providing a first valid signal in response said done signal.

14. The locally asynchronous logic circuit of claim 13 wherein said synchronous-to-asynchronous control circuit further activates said latch enable signal in response to said first clock signal when a second valid signal is active.

15. The locally asynchronous logic circuit of claim 13 wherein said synchronous-to-asynchronous control circuit further activates a first ready signal after an activation of said latch enable signal.

16. The locally asynchronous logic circuit of claim 15 wherein said asynchronous-to-synchronous control circuit activates a second ready signal in response a second clock signal.

17. The locally asynchronous logic circuit of claim 16 wherein said measured characteristic of said asynchronous functional circuit comprises an amount of time required by said asynchronous functional circuit to perform said predetermined operation.

18. A method for timing a locally asynchronous logic circuit comprising:
latching first input data and activating a start signal in response to a first clock signal when a first valid signal is active;
performing a first functional operation on the input data so latched and providing first output data in response;
determining a first completion time for said first functional operation in response to said start signal, and providing a first done signal in response to the determining;
providing an output of the locally asynchronous logic circuit in response to said first output data and said first done signal; and
latching said output of the locally asynchronous logic circuit in response to a second clock signal and said done signal.

19. The method of claim 18 wherein said providing comprises:
latching said first data output in response to said done signal;
performing a second functional operation on said first output data so latched and providing second output data in response to determining a second completion time for said second functional operation and providing a second done signal in response;
providing said output of the locally asynchronous logic circuit further in response to said second output data and said second done signal; and
latching said output of the locally asynchronous logic circuit in response to said second clock signal after said first and second completion times have elapsed.

20. The method of claim 18 further comprising:
repeating latching output data, performing additional functional operations, and determining completion times of said functional operations for a predetermined number of times;
providing said output of the locally asynchronous logic circuit further in response to said additional functional operations; and
latching said output of the locally asynchronous logic circuit in response to said second clock signal after all completion times have elapsed.
